(19) United States
(12) Patent Application Publication
(10) Pub. No.: US 2022/0376517 A1
(43) Pub. Date: Nov. 24, 2022

(54) SYSTEMS AND METHODS FOR BATTERY PACK CHARGE BALANCING

(71) Applicant: Iontra LLC, Denver, CO (US)

(72) Inventors: Daniel A. KONOPKA, Denver, CO (US); John Richard HOWLETT, III, Centennial, CO (US); Jeffrey J. HOLT, Superior, CO (US)

(21) Appl. No.: 17/750,143

(22) Filed: May 20, 2022

Related U.S. Application Data
(60) Provisional application No. 63/191,138, filed on May 20, 2021.

(51) Int. Cl. H02J 7/00; G01R 31/396; G01R 31/389

(52) U.S. Cl. CPC H02J 7/0016; G01R 31/396; G01R 31/389; G01R 31/367

(57) ABSTRACT

A system is disclosed for charging (recharging) and discharging a battery pack comprising a plurality of battery cells. The system may execute an iterative process of monitoring a frequency corresponding to the minimum impedance value of the battery pack or cell(s) of the pack and adjusting the charge energy signals applied to the battery pack. In some instances, taps may be provided within the battery pack to monitor the frequency response to the charge energy signal for one or more cells of the battery pack. In other instances, the battery pack as a unit may be monitored iteratively. This process may maintain a relative charge balance across the cells of the battery pack, decrease the time to recharge the battery pack, extend the life of the pack, optimize the amount of current charging the battery pack, and avoid energy lost to various inefficiencies.

### CROSS-REFERENCE TO RELATED APPLICATIONS

This application is related to and claims priority under 35 U.S.C. § 119(e) to U.S. Patent Application No. 63/191,138 filed May 20, 2021 entitled “Systems and Methods for Battery Pack Charge Balancing,” the entire contents of which is incorporated herein by reference for all purposes.

### TECHNICAL FIELD

Embodiments of the present invention generally relate to systems and methods for charging or discharging battery cells interconnected to form a battery pack, and more specifically to generation of a high-efficiency charging or discharging signal to provide for a balanced charging and/or balanced capacity between cells of the battery pack.

### BACKGROUND

Many electrically-powered devices, such as power tools, vacuums, any number of different portable electronic devices, and electric vehicles, among others, use rechargeable batteries as a source of operating power. Rechargeable batteries are limited by finite battery capacity and must be recharged upon depletion. Recharging a battery may be inconvenient as the powered device must often be stationary during the time required for recharging the battery. In the case of vehicles, recharging the high capacity battery packs can take hours. As such, significant effort has been put into developing rapid charging technology to reduce the time needed to recharge the battery. However, rapid recharging systems are typically inefficient while lower rate recharging systems prolong the recharging operation, undermining the basic objective of a quick return to service.

In addition to the above shortcomings, many rechargeable batteries include a plurality of individual cells connected in some combination of series and/or parallel to form a battery pack. For example, a group of rechargeable cells may be connected in series to form a battery pack, a group of rechargeable cells may be connected in parallel to form the battery pack, some rechargeable cells may be connected in series to form groups or modules, which are then connected in parallel to form the battery pack, and the like. Regardless of the interconnections of the cells, recharging of the battery pack often includes providing a charge signal to that is distributed to the interconnection of cells. However, due to variations in physical and/or chemical characteristics of the cells of the battery pack, the charges of the cells may become unbalanced due to various possible reasons including initial capacity differences, and uneven charging and discharging possibly also including over charging and over discharging. Cells may have capacity variations when manufactured simply due to tolerance errors, manufacturing variances, chemical constituent differences and other differences between cells at the time of manufacturing. Cells may also change differently during charge cycles for any number of reasons including heat differences, charge distribution differences, as well as discharge differences. As cells become unbalanced over time and charge/discharge cycles, the differences can cause further imbalances, e.g., from cells over charging or over discharging further damaging those cells, can degrade the capacity of the overall pack depending on the charge and discharge algorithms used, and have other detrimental effects.

It is with these observations in mind, among others, that aspects of the present disclosure were conceived and developed.

### SUMMARY

One aspect of the present disclosure relates to a method for charging an electrochemical device. The method may include the operations of accessing a plurality of harmonic profiles that each indicate a relationship between at least one harmonic and an impedance of each of a plurality of electrochemical devices comprising a plurality of electrochemical cells arranged in an electrochemical pack, determining a relative charge value for each of the plurality of electrochemical cells; and controlling, based on the relative charge value for each of the plurality of electrochemical cells, an energy signal at an electrode of the electrochemical pack, the energy signal at a harmonic associated with a minimum impedance value of a target electrochemical cell of the plurality of electrochemical cells.

Another aspect of the present disclosure relates to a battery pack charging system. The system may include a charge signal shaping circuit in communication with an electrochemical pack comprising a plurality of electrochemical cells, an impedance measurement circuit in communication with the electrochemical pack to obtain an impedance measurement of each of plurality of electrochemical cells, and a controller. The controller determines a relative charge value for each of the plurality of electrochemical cells, identifies, based on the relative charge value for each of the plurality of electrochemical cells, a target electrochemical cell of the plurality of electrochemical cells, and controls the charge signal shaping circuit to shape a charge signal for the target electrochemical cell based on a harmonic associated with the minimum impedance value of the target electrochemical cell.

Yet another aspect of the present disclosure relates to a method for balance charging of a battery pack. The method may include the operations of obtaining, based on an indication of a charge of a first cell of a plurality of electrochemical cells being less than an indication of a charge of a second cell of the plurality of electrochemical cells, a minimum impedance value of the first cell and shaping a charge signal for the plurality of electrochemical cells to include a harmonic associated with the minimum impedance value of the first cell, the charge signal to charge the first cell.

### BRIEF DESCRIPTION OF THE DRAWINGS

The foregoing and other objects, features, and advantages of the present disclosure set forth herein should be apparent from the following description of particular embodiments of those inventive concepts, as illustrated in the accompanying drawings. The drawings depict only typical embodiments of the present disclosure and, therefore, are not to be considered limiting in scope.

FIG. 1A is a bar graph of the voltage output of a plurality of cells of a battery pack prior to which a balancing procedure may be applied.

FIG. 1B is a graph of estimated real impedance values of a battery cell to corresponding frequencies of a charge signal applied to the battery cell in accordance with one embodiment.

FIG. 2 is a schematic diagram illustrating a circuit for charging a battery pack utilizing a charge signal shaping circuit in accordance with one embodiment.

FIG. 3A is a schematic diagram illustrating a first example battery pack configuration comprising multiple battery cells.

FIG. 3B is a schematic diagram illustrating a second example battery pack configuration comprising multiple battery cells.

FIG. 4 is a graph of determined impedance values of a battery cell to corresponding frequencies of a charge signal applied to the battery cell in accordance with one embodiment.

FIG. 5 is a signal diagram of a shaped battery signal charge signal including a leading edge portion and a body portion generated from a battery charge circuit in accordance with one embodiment.

FIG. 6 is a graph of a determined impedance values of a battery pack to corresponding frequencies of a charge signal applied to the pack with an indicated maximum and minimum frequency in accordance with one embodiment.

FIG. 7 is a flowchart illustrating a method for generating a charge signal for a battery pack based on a frequency corresponding to a minimum impedance value in accordance with one embodiment.

FIG. 8 is a flowchart illustrating a method for generating a charge signal for a battery pack to charge or discharge a cell of the battery pack in accordance with one embodiment.

FIG. 9 is a diagram illustrating an example of a computing system which may be used in implementing embodiments of the present disclosure.

### DETAILED DESCRIPTION

Systems, circuits, and methods are disclosed herein for charging (recharging) and discharging a battery pack comprising a plurality of electrochemical battery cells. The terms charging and recharging are used synonymously herein. Through the systems, circuits, and methods discussed, a pack may be charged and discharged with less unbalancing effect as compared to conventional techniques. Moreover, aspects of the present disclosure involve systems and methods that may balance cells should they become unbalanced. Moreover, unlike conventional techniques, the balancing technique may be employed with a charge signal applied to unbalanced cells as well as some or all of the other cells of the pack.

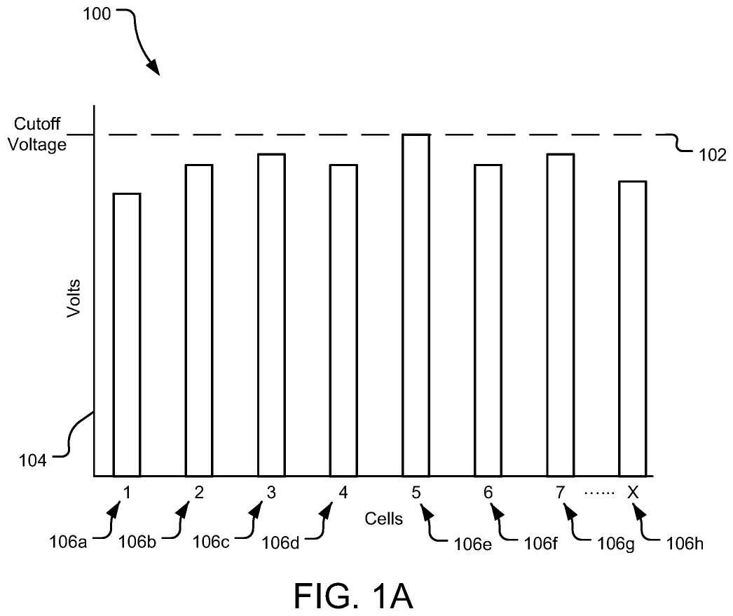

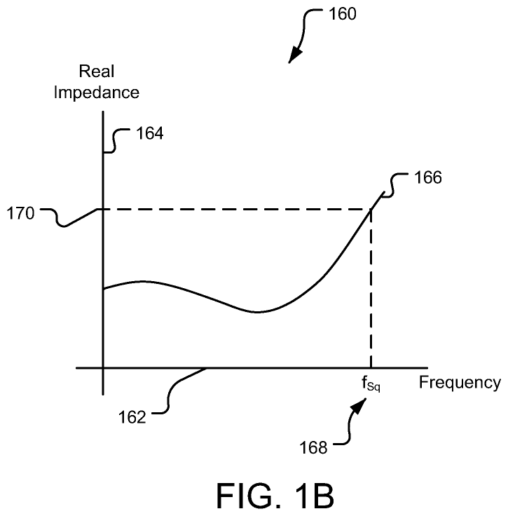

Battery packs may include any number of cells coupled in any manner, such as in parallel, series, parallel and series, and the like. Generally speaking, a battery pack may be recharged through the application of a recharging power signal from a controllable power source. However, charging of a battery pack may result in an unbalanced state of charge for the cells of the pack. For example, FIG. 1A is a bar graph 100 illustrating voltage measurements 104 of various discrete cells of a battery pack. Voltage measurements may be made while charging, discharging or at rest. Regardless, as cells in a pack become unbalanced, often the voltage measurement at the terminals of different cells of a pack will be different. The terminal voltage of a cell will tend to rise over time while a cell is being charged. If cells are equal and receive equal energy, the cell voltages will be about the same at the same state of charge.

As shown in FIG. 1A, the terminal voltage 106a-h for a plurality of cells (indicated as cells 1-X) of an example battery pack is illustrated in the graph 100. As illustrated, each of the cells of the battery pack has a different voltage 106a-h, reflecting imbalances between the cells. In some conventional techniques, charging of the cells of the battery pack may be cutoff when the output voltage of one of the cells reaches a cutoff voltage value 102. For example, charging of the battery pack associated with the graph 100 of FIG. 1A may cease when the output voltage of cell 5 106e reaches the cutoff voltage 102. However, in this example, the remaining cells of the battery pack are not yet charged to the cutoff voltage 102 such that the battery pack is not fully charged due to charging being stopped before all cells reach the cutoff voltage indicative of a fully charged cell. It should be noted that the cutoff voltage may be specified by the manufacturer or identified by other means.

Several responses to the unbalanced charging of a battery pack have been proposed. In one example, the charge signal may be applied to the battery pack until each cell of the battery pack has reached the cutoff voltage 102. However, this may result in one or more of the cells becoming under- or over-charged, resulting in poor capacity utilization, non-uniform capacity between cells, or damage to a cell, sometimes catastrophic damage to the cell and the battery pack. To avoid either the over-charging or under-charging of one or more cells of the pack, a charging circuit may include a charge balancer. In general, the charge balancer may monitor and adjust the charge of the cells of the battery pack in an attempt to keep the charges of each cell balanced. In one particular implementation, the charge balancer may monitor an output voltage of each cell and, when the output voltage reaches the cutoff voltage 102, may activate a discharge resistor connected to the monitored cell to maintain the voltage of the cell at the cutoff voltage until each cell has reached the cutoff voltage. In other instances, the charge balancer may redirect the charge signal away from cells with a higher charge to cells with a lower charge in an attempt to keep the available voltage of the cells balanced. Regardless of the balancing technique used by the charge balancer, balancing of the cells of the battery pack may negatively affect the charging process of the battery pack, particularly in fast charge scenarios. For example, the balancing of the cells of the battery pack may slow down the overall charging process and may consume more charge energy as some of the charge signal is dissipated through a discharge resistor. Other solutions for cell balancing may also be expensive and difficult to manage.

In addition to the inefficiencies introduced through cell balancing, the use of a charging scheme involving square-wave charge pulses may further degrade the life of the cells and exacerbate or accelerate unbalancing of the battery pack under recharge or may introduce other inefficiencies in the recharging of the battery pack. For example, the abrupt application of charge current (i.e., the sharp leading edge of the square-wave pulse) to the electrode (typically the anode) of the cell of the battery pack may cause a large initial impedance across the terminals cell. FIG. 1B illustrates a graph of estimated real impedance values of a typical battery cell to corresponding frequencies of a recharge signal applied to the cell. In particular, the graph 160 illustrates a plot of real impedance values (axis 164) versus a logarithmic frequency axis (axis 162) of frequencies of an input signal to the cell 106. The plot 160 illustrates real impedance values across the electrodes of a cell at the various frequencies of a recharge power signal used to recharge a battery pack. The shape and measured values of the plot 160 may vary based on cell type, state of charge of the cell, operational constraints of the cell, heat of the cell, configuration of cells in the battery pack, mechanical and chemical characteristics of cells in the battery pack, and the like. However, a general understanding of the characteristics of a cell under charge may be obtained from the plot 166 of impedance values versus frequency. In particular, real impedance values experienced at the electrodes of the cell may vary based on the frequency of the power charge signal provided to the cell, with a general sharp increase in real impedance values 166 at high frequencies. For example, an input power signal to the battery cell at frequency f_{Sq} 168 may introduce a high real impedance at the battery cell electrodes.

Use of a square-wave charge signal to recharge a battery pack may introduce large frequencies at the leading edge of the square-wave pulse. In particular, the rapid changes in the charge signal to the battery cell may introduce noise comprised of high-frequency harmonics, such as at the leading edge of a square-wave pulse, and during use of conventional reverse pulse schemes. As shown in the graph 160 of FIG. 1B, such high harmonics result in a large impedance at the battery cell electrodes. This high impedance may result in many inefficiencies, including capacity losses, heat generation, and imbalance in electro-kinetic activity throughout the battery cell, undesirable electro-chemical response at the charge boundary, and degradation to the materials within the battery cell that may damage the battery and degrade the life of the battery cell. One particular issue of high frequency/high impedance harmonic content may cause plating and plating may affect each cell differently. Plating, in turn, effects how the cell takes energy during charge and thus may exacerbate cell unbalancing. Further, cold starting a battery with a fast pulse introduces limited faradaic activity as capacitive charging and diffusive processes set in. During this time, proximal lithium will react and be quickly consumed, leaving a period of unwanted side reactions and diffusion-limited conditions which negatively impact the health of the cell and its components, which again may then result in unbalancing between cells in the pack.

In addition, these inefficiencies may lead to unbalanced charging of a battery pack. For example, capacity loss in a cell of the battery pack may result in the cell being incapable of reaching a cutoff voltage, even when fully charged, such that the cells of the battery pack remain unbalanced. In another example, inefficiencies in charging of cell may cause that cell to charge at a slower rate than other cells in the battery pack, causing the charge balancer to have to dissipate more energy from the faster charging cells during the charging process. The charge balancer may become more inefficient over time during the life of a battery pack to compensate for the damage done to the cells of the pack over multiple charge and discharge sessions.

Aspects of the present disclosure may provide several additional advantages, alone or in combination, relative to conventional charging of a battery pack. For example, the charging techniques described herein may allow for higher charging rates to be applied to a battery pack of cells, and may thus allow for faster charging as compared to conventional techniques. During what might be considered normal charging rates, the techniques described herein may provide for greater relative cycle life—i.e., the pack may be able to be charged and discharged a relatively higher number of times before falling below some threshold—e.g., capacity. In one example, during what might be considered “slow charging” of the battery pack, the disclosed systems and methods provide for a longer life of the cells of the pack and charging energy efficiency. In another example, in what might be considered “fast charging,” the disclosed systems and methods provide an improved balance of charge rate and cell life, while producing less heat. Further, aspects of the present disclosure operate to keep the cells of a battery pack balanced during charging of the cells of the pack. While various aspects of the present disclosure are discussed with respect to comparisons to performance or effect of conventional techniques, it should be recognized that the technique, system or the like is itself inventive irrespective of the various possible benefits set out herein.

In one example, the various embodiments discussed herein charge or discharge a battery pack by generating a charge signal composed of targeted harmonics associated with an optimal transfer of energy based on a real and/or an imaginary impedance to the energy transfer of the battery pack, a plurality of cells of the battery pack, or a particular cell of the battery pack. In one specific example, the charge or discharge signal may be a sequence of energy signals specifically shaped and or composed of one or more harmonic components associated with a minimum impedance (real and/or imaginary) value of the battery pack or cell(s). In another example, the energy signals of the signal correspond to a harmonic associated with both the real and imaginary impedance value of the battery pack or cell(s) of the pack. In still another example, the energy signals of the signal may correspond to a harmonic associated with one or both of a conductance or susceptance of an admittance of the battery pack or cell(s) of the pack. Given the generally inverse relationship, the term impedance as used herein may include its inverse admittance, including its constituents of conductance and susceptance alone or in combination. More particularly, systems and circuits are described that determine a frequency corresponding to the minimum impedance value of some aspect of the battery pack. In another example, the system may generate an impedance spectrum identifying a range of frequencies including the frequency at or near the minimum impedance. In some examples, since the frequency at which a minimum impedance occurs may change due to state of charge, temperature, and other factors, the techniques discussed herein may reassess the minimum impedance frequency of the pack. The circuits may shape or otherwise generate energy signals of a charge signal (e.g., charge current) corresponding to the harmonics or frequencies at or near a determined minimum impedance.

The circuits described herein may, in some instances, perform an iterative process of monitoring or determining a frequency corresponding to the minimum impedance value of the battery pack or cell(s) of the pack and adjusting the energy signals applied to the battery pack. In some instances, taps may be provided within the battery pack to monitor the frequency response to the charge energy signal for one or more cells of the battery pack. In other instances, the battery pack as a unit, may be monitored iteratively. This process may improve the efficiency of the charge signal used to recharge the battery pack, thereby maintaining a relative charge balance across the cells of the battery pack, decreasing the time to recharge the battery pack, extending the life of the pack (e.g., the number of charge and discharge cycles it may experience), optimizing the amount of current charging the battery pack, and avoiding energy lost to various inefficiencies, among other advantages. For example, as high impedance in a charge signal may result in many inefficiencies, such as capacity losses, heat generation, degradation to the materials within the battery cell, and the like, a charge rate of each cell of a battery pack may begin to vary over multiple recharge and discharge cycles, leading to a potential imbalanced charge of the cells of the battery pack. By limiting these negative effects on the cells, a more balanced charge of a battery pack may occur as the changes to the characteristics of each cell are mitigated by harmonic-based charge energy signal shaping.

In some instances, the charging techniques described herein may aid in balancing cells of a battery pack by targeting specific cells within the battery pack for charging or discharging differently than other cells in the pack. Firstly, the system may assess cells of a pack to detect whether cells are or are becoming imbalanced. Particular cells of the pack may then be targeted for rebalancing. The frequency or harmonics associated with low impedance measurements for such cells may be determined from an analysis of a response of the cells to a charge signal and a subsequent charge signal may be altered or generated, based on the determined frequency response of a cell, to either charge or discharge the unbalanced cell (or cells) of the battery pack differently than other cells to bring the cells into balance. In such a technique, harmonics are tailored to a specific cell or cells to balance the cells of a pack. Through identification of particular harmonics corresponding to one or more cells of the battery pack, the harmonic content of the signal itself may be tailored to maintain a charge balance of the cells of the pack to avoid the detrimental effects when packs become unbalanced. Further, shaping of the charge signal to target particular cells of a battery pack may be used alone or in conjunction with a charge balancer to improve a charge balancing procedure for the battery pack.

The systems, circuits, and methods disclosed herein are applicable to charging any form of a battery pack that may comprise some number of cells connected in some way to achieve a desired capacity, voltage and output current range for whatever application the battery pack is being used. The various embodiments discussed herein may also be considered to provide fast charging. In either or both situations, and in the specific context of a charge signal including energy signals, the charge circuit may be controlled to generate charge energy signals that include a shaped rising front edge rather than a sharp edge associated with a conventional square-wave pulse. In one example, the rising front edge of a charge energy signal may be based on a determined frequency (harmonic) corresponding to a harmonic associated with a minimum or near minimum real and/or imaginary impedance value of the battery pack, cells of the battery pack, or a particular cell of the battery pack. The charge energy signal may also be based on a combination of the minimum real impedance and imaginary impedance of the pack or cell(s). In another example, the charge energy signal may be based on a conductance and/or susceptance, or any other admittance aspect, either alone or in combination, of the battery pack being charged. Still other aspects of the battery pack or cell(s) may be considered and used to shape a charge energy signal. Generally speaking, where real and imaginary impedance values are being considered, the technique assesses harmonic values where the values, alone or in combination, are based on an aspect of impedance of the battery feature to the harmonic, and the system seeks to generate the charge signal responsive to the impedance.

Discussing, for the moment, a generated charge energy signal based on the harmonics with a minimum real impedance of a cell, the application of the rising front edge having a shape of a harmonic corresponding to the near minimum real impedance value may optimize the energy transfer to the cell. At the same time, the system may define the charge signal such that it does not include harmonic content that may have a large impedance at the cell or other detrimental effects. In this manner, a harmonically tuned charge signal may be applied through control of the circuit to deliver an optimized amount of power to the battery pack while removing high frequency, degrading harmonics from the signal. This shaped charge signal may therefore reduce the impedance across the various interface within the battery pack during charge of the battery pack, thereby maintaining a charge balance across the cells of the battery pack for a more efficient charging of the battery pack.

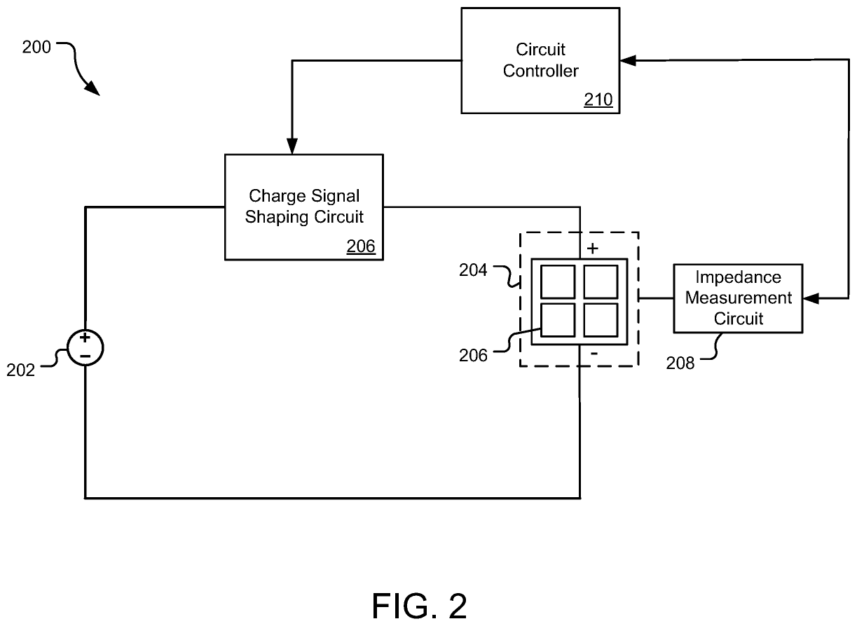

FIG. 2 is a schematic diagram illustrating a circuit 200 for recharging a battery pack 204 that includes a plurality of cells 206 utilizing a charge signal shaping circuit 206 and an impedance measurement circuit 208 in accordance with one embodiment. In general, the circuit 200 may include a power source 202, which may be a voltage source or a current source. In one particular embodiment, the power source 202 is a direct current (DC) voltage source, although alternating current (AC) sources are also contemplated. In general, the power source 202 supplies the charge current to the charge signal shaping circuit which shapes charge signal for application to the battery pack 204. In one particular implementation, the circuit 200 of FIG. 2 may include a charge signal shaping circuit 206 to shape one or more energy signals of a charge signal for use in charging the battery pack 204. In one example, a circuit controller 210 may provide one or more inputs to the power signal shaping circuit 206 to control the shaping of the charge signal. The inputs may be used by the shaping circuit 206 to alter a signal from the power source 202 into a more efficient power charging signal for the battery pack 204. The operation and composition of one example of the charge signal shaping circuit 206 is described in more detail in U.S. Nonprovisional patent application Ser. No. 17/232,975 entitled “Systems and Methods for Battery Cell Charging”, filed on Apr. 16, 2021, the entirety of which is incorporated by reference herein. Other charge signal shaping circuit implementations may also be utilized with the techniques described herein to charge a battery pack.

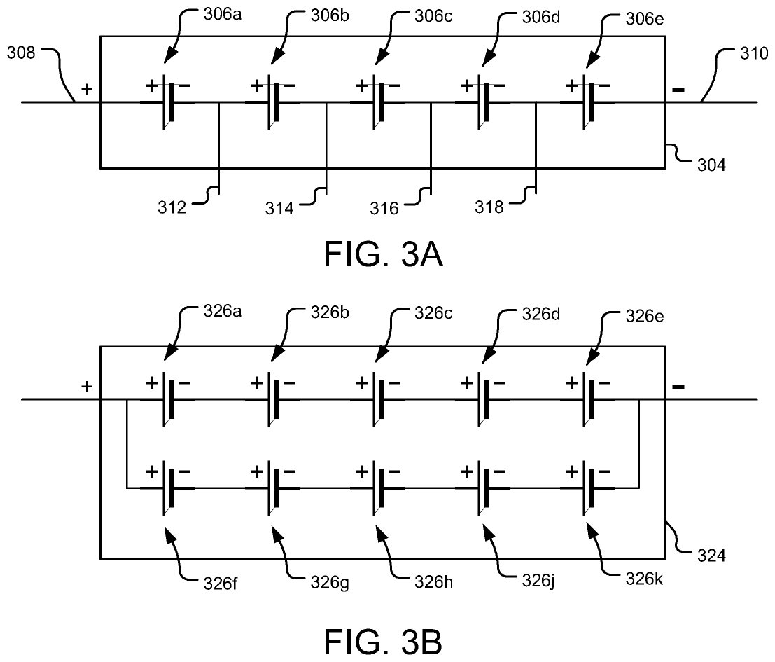

In some instances, the charge signal shaping circuit 206 may alter energy from the power source 202 to generate a charge signal that at least partially corresponds to a harmonic associated with a minimum real impedance value associated with the battery pack 204, multiple cells of the battery pack, or a particular cell of the pack. It is also possible to characterize a battery pack or cell(s) such that impedance may be known at any given charge current, voltage, charge, number of charge/discharge cycles, and/or temperature among other factors, such that impedance is not directly measured but instead obtained from memory, or the like. In one example, the circuit 200 may include an impedance measurement circuit 208 connected to the battery pack 204 to measure cell voltage and charge current, as well as other cell attributes like temperature and measure or calculate the impedance across the electrodes of the battery pack 204 or cells 206 of the pack. In particular, the impedance measurement circuit 208 may connect to a first and second electrode of the battery pack 204 to obtain performance or state data of the battery pack. In other examples, data or measurements may be obtained from the battery pack 204 via one or more measurement taps included in the battery pack. For example, FIG. 3A is a schematic diagram illustrating a first example battery pack configuration 304 comprising multiple battery cells 306a-306e and FIG. 3B is a schematic diagram illustrating a second example battery pack configuration 324 comprising multiple battery cells 326a-326k. Battery pack 204 of circuit 200 may have a similar configuration the battery pack 304 of FIG. 3A or battery pack 324 of FIG. 3B, or any other configuration of cells connected in a combination of series and/or parallel connections. The battery packs 304, 324 of FIGS. 3A and 3B are provided herein merely as examples of possible battery pack configurations.

Battery pack 304 illustrates multiple battery cells 306a-306e connected in a series configuration. In general, the battery pack 304 may function electrically as a single battery cell to provide power to a load connected to electrodes 308, 310. To charge the battery pack 304, a charge signal may be applied to a first electrode 308 (such as the anode) of the battery pack 304 of cells. The charge signal may propagate through the cells 306a-306e of the battery pack 304, with each cell absorbing energy from the charge signal. Battery pack 324 illustrates a second configuration of battery cells 326a-326e, more particularly a first set of multiple cells 326a-326e connected in series and a second set of multiple cells 326f-326k connected in series, with each series connected in a parallel configuration. Other configurations of battery cells may also be utilized in other battery packs to provide power signals to a load and may be charged using techniques, circuits, and systems described herein.

As mentioned above, the impedance or other characteristics of the battery pack may be determined from measurements taken of the battery pack 204 or individual or groups of cells 206 of the battery pack. For example, an overall impedance of the battery pack 304 of FIG. 3A may be determined through a connection of the impedance measurement circuit 208 to electrode 308 and electrode 310 of the battery pack 304. In other instances, impedance or other characteristics of one or more cells 306a-306e of the battery pack 304 may be measured or determined. For example, one or more taps 312-318 may be included in the battery pack 304 that provides access to the connections within the battery pack between the cells of the pack. Through a connection of measurement devices to the available taps 312-318, impedances or other characteristics of a cell or cells 306a-306e within the battery pack 304 may be obtained or determined. As described in more detail below, the impedance determination may be utilized to generate or configure a charge signal to the battery pack 304 to target particular cells within the pack or otherwise maintain a charge balance between the cells of the battery pack 304 during charging of the pack.

In one example, impedance of the battery pack 204 or cells 206 within the pack may be determined as responsive to the harmonically tuned signal (e.g., energy signals) of the charge signal. Impedance may also be determined as part of a routine that applies a signal with varying frequency attributes to generate a range of impedance values associated with different frequency attributes of the cell to characterize the pack or cells, which may be done prior to charging, during charging, periodically during charging, and may be used in combination with look-up techniques, and other techniques. The impedance may include a real value and an imaginary or reactance value. The impedance of the battery pack 204, cells 206, or cell of the pack may vary based on many physical of chemical features of the battery pack, including a state of charge and/or a temperature of the cells 206 of the battery pack 204. As such, the impedance measurement circuit 208 may be controlled by the circuit controller 210 to determine various impedance values of the battery pack 204 during recharging of the cell, among other times, and provide the measured impedance values to the circuit controller 210. In some instances, an imaginary component (or reactance) of the determined impedance of the battery pack 204 may be provided to the charge signal shaping circuit 206 by the circuit controller such that energy from the power source 202 may be sculpted into one or more charge signals that correspond to a harmonic associated with a minimum imaginary impedance value of the battery pack 204 or cell(s) 206 of the pack. In another example, the circuit controller 210 may generate one or more control signals based on the received reactance value and provide those control signals to the charge signal shaping circuit 206. The control signals may, among other functions, shape the charge signals to include a harmonic component corresponding to the reactance value. In still other examples, the charge signal shaping circuit 206 may alter energy from the power source 202 to generate a charge signal that at least partially corresponds to a harmonic associated with a conductance or susceptance component of an admittance of the battery pack 204 or any other aspect related to an impedance at the battery cell. Thus, although described herein as pertaining to a real or imaginary component of impedance, the systems and methods may similarly measure or consider other attributes of the battery cell, such as a conductance component or susceptance component of an admittance of the battery cell.

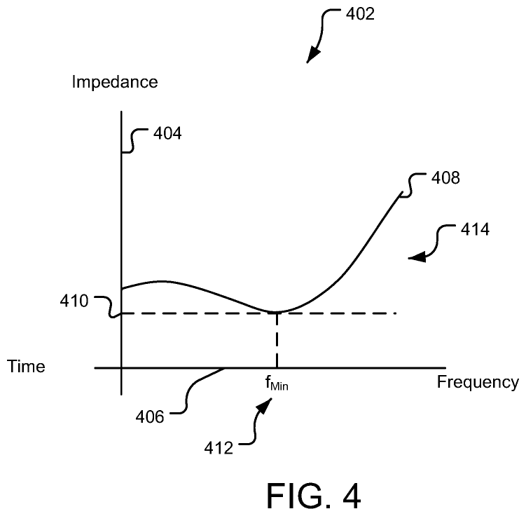

FIG. 4 is a graph 402 of determined impedance values of a battery pack 204 to corresponding frequencies of a charge signal applied to the battery pack in accordance with one embodiment. In particular, the graph 402 illustrates a plot of impedance (either real, imaginary, or a combination of both) values (axis 404) versus a logarithmic frequency axis (axis 406) of a charge signal. The plot 408 illustrates impedance values across the electrodes of a battery pack 204 at the various frequencies of a charge signal. As shown, the impedance values 408 may vary based on the frequencies of the charge signal, with a general rapid increase in impedance values 408 at the highest frequencies. The plot 414 of impedance values for the battery pack 204, however, also indicates a minimum impedance value 410 that corresponds to a particular charge signal frequency, labeled as f_{Min}. The plot of impedance values 414 for the battery pack 204 may be dependent on many factors of the pack or cells of the pack, such as battery chemistry, state of charge, temperature, composition of charge signal, and the like. Thus, the frequency f_{Min} 412 corresponding to the minimum impedance value 410 of the battery pack 204 may similarly be dependent upon the characteristics of the particular battery pack 204 under charge. The frequency f_{Min} 412 may correspond to other aspects of the battery pack 204, such as the configuration of the cells in the pack and the connections between the cells in the pack.

As the impedance of the cells 206 of the battery pack 204 may convert received power to heat or other inefficiencies, generating a charge signal that includes the frequency 412 corresponding to the minimum impedance value 410 for the battery pack 204 or cell(s) may improve the efficiency of charge energy application to the battery pack. In other words, defining or shaping the charge signal to include harmonics at or near the frequency f_{Min} 412 may increase charging efficiency, reduce damage to the cell, control heat generation and other benefits. As is discussed herein, various aspects of the charge signal may include harmonics. In one example, the leading edge of a charge energy signal may be shaped according to a harmonic. In another example, the trailing edge of a charge energy signal may be shaped according to a harmonic. In another example, a body of a charge energy signal may be composed of harmonics at or near the frequency associated with some minimum impedance. In yet another example, charge energy signals may comprise various combinations of harmonically tailored leading edge, trailing edge and body.

As such, one implementation of the recharge circuit 200 of FIG. 2 may include the impedance measurement circuit 208 connected to the battery pack 204 or taps of the battery pack to determine various impedance values of the battery pack over a range of frequencies of the charge signal. The impedance measurement circuit 208 may include any known or hereafter circuit configured to gather information sufficient to determine impedance of the battery pack 204 or cells from various taps of the battery pack. In one example, the impedance measurement circuit includes a voltage sensor and a current sensor, from which voltage and current measurements are taken and impedance may be computed. Multiple impedance values of the battery pack 204 may be measured at various frequencies of a charge power signal and provided to the circuit controller 210 which may, in turn, determine or estimate the minimum impedance value of the curve 414 of the battery cell 204. In one implementation, the circuit controller 210 may determine a reactance component of the impedance value. The circuit controller 210 may also control one or more components of the charge signal shaping circuit 206 to generate a series of charge energy signals at a harmonic of the frequency f_{Min} 412 corresponding to the minimum impedance 410 value of the battery pack 204. As further explained below, the circuit controller 210 may also conduct an iterative process of measuring or otherwise determining an estimated impedance value for a current state of the battery pack 204 at various times during a recharge session and adjust the energy signals of the charge power signal 414 accordingly to coincide with the new estimated frequency f_{Min} 412.

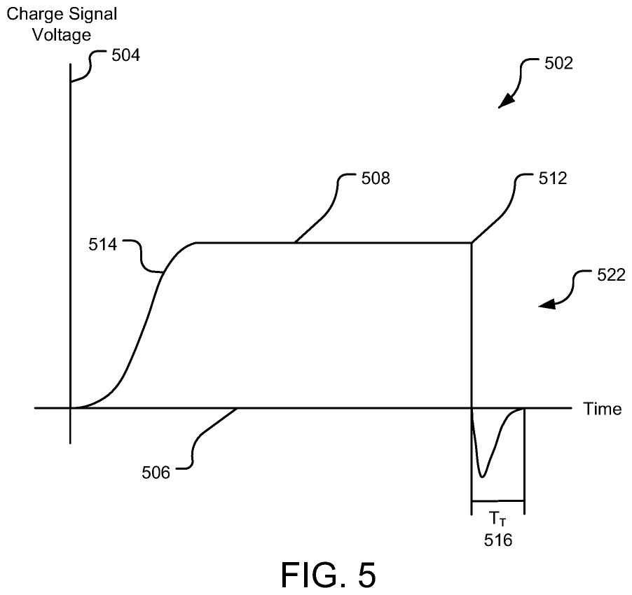

FIG. 5 illustrates an example of a charge signal that may be generated by the circuit controller 210 and/or the charge signal shaping circuit 206 to include an identified harmonic in the charge signal to balance the charges of the cells 206 of a battery pack 204. In one example, the charge signal shaping circuit 206, based on one or more control signals provided by circuit controller 210, may generate shaped harmonically tuned energy signal 522. Further, the energy signal 522 may be one of many such energy signals provided to charge the pack. In the example of FIG. 5, the signal diagram 502 illustrates voltage signal current 504 versus time 506. As can be seen, the energy signal 522 is asymmetric with a leading edge 514 distinctly shaped relative to the trailing edge 512. In general, various portions of the shaped energy signal 522 (such as the leading edge 514, the trailing edge 512, and/or content of energy signal body 508) may be composed of particular harmonics. Thus, in some instances, the energy signal 522 may be defined or shaped by a combination of harmonics corresponding to or related to a minimum impedance value seen at the battery cell electrodes as discussed above. In particular, the charge signal energy signal 522 may include a leading edge portion 514 that corresponds to a selected frequency that relates to the minimum impedance value for the battery pack 204. For example, the shape of the leading edge 514 of the energy signal 522 may correspond to a harmonic f_{Min} 412 identified by the control circuit 210 as the frequency at a minimum impedance value at the battery pack. In one example, the leading edge 514 shape may be based on the leading edge of a corresponding sinusoid at the frequency of minimum impedance. Identifying the minimum impedance frequency may be based on a measurement (or measurements), battery characterization, alone or in combination, among other things of the battery pack 204, multiple cells 206 of the battery pack, or a single cell of the battery pack. Regardless of the selected frequency, the leading edge 514 of the energy signal 522 may be the shaped to be the same as the leading edge of a portion of a charge signal at a harmonic that minimizes or reduces the impedance seen at the battery pack for a more efficient application of a power recharge signal through a balancing of the cells 206 of the battery pack 204.

At some later time in the energy signal 522, a magnitude of the energy signal may reach an upper or floating voltage or current corresponding to the constant current at the top of the energy signal 508. A duration of the energy signal 522 may be controlled by the circuit controller 210 to provide a power charge to the cells 206 of the battery pack 204 and may be based on characteristics of the cells of the pack, such as cell composition, orientation and connection of the cells, state of charge of the cells, temperature of the cells, and the like. The body 508 of the energy signal may be composed of a collection of harmonics associated with the same frequency of the minimum impedance.

In some instances, the energy signal 522 may be controlled to include a sharp falling edge 512 to remove charge to the cells following the energy signal 522. Although a sharp falling edge 512 may include a high frequency harmonic component, such harmonics may not increase the damaging impedance at the battery pack 204 as current and voltage magnitudes are approaching or equal to zero (zero overpotential in the case of voltage) across the battery pack following the sharp falling edge. This dissociation between higher harmonics and damaging impedance remains true when the charge signal magnitude is temporarily decreased below the battery's float voltage (e.g., the battery voltage when not receiving a charge current and illustrated in time T_{T} 516) so as to decrease the time required for the charge current to reach zero. More particularly, the current at the battery pack 204 may take some time to return to zero after the current to the battery pack is removed. This delay in the current at the battery returning to zero may add additional inefficiencies to the charge signal 522. Therefore, in some implementations, the charge signal may be controlled to drive the voltage below a transition voltage corresponding to a zero current. Driving the charge signal 522 below a transition voltage for a period of time (illustrated as period T_{T} 516) following the falling edge 512 of the energy signal 522 may drive the current to zero amps at a faster rate as compared to an energy signal without the trailing blip. The duration T_{T} 516 during which the charge signal 522 is controlled below the transition voltage corresponding to a zero current may be determined or set by the circuit controller 210 to minimize the time for the current at the battery pack 204 to return to zero amps. Once the charge signal 522 has returned to zero amps for a particular rest period, another charge energy signal may be applied to the battery pack 204. Thus, reduction in the time needed for the current at the battery pack 204 to return to zero may increase the rate at which the charge energy signals may be applied to charge the battery cell.

In this manner through control of the charge signal shaping circuit 206, a shaped charge energy signal 522 may be created that includes a sinusoidal leading edge 514 at a harmonic that corresponds to a minimum impedance value of a battery pack 204 or cell(s) 206 of the pack, a duration at an upper magnitude 508, and a sharp falling edge 512 that provides sufficient charge to the battery pack 204 while maintaining a low impedance at the pack electrodes. Further, reduction of the impedance to the cells 206 of the battery pack 204 through the application of shaped charge energy signal 522 may keep the charge of the cells balanced such that additional discharging or displacement of energy from one cell to another may be reduced, increasing the efficiency of the charging of the battery pack 204.

Implementations discussed above involve measuring or otherwise obtaining the impedance of a battery pack 204 or cell(s) 206 of the battery pack, real and/or imaginary, to determine a frequency component of at least a portion of an energy signal of a charge signal. The impedance values of the battery pack 204 may be obtained in a variety of ways or methods. In one implementation, the impedance at the battery pack 204 may be measured or estimated in real-time as a charge signal is applied to the battery pack. For example, aspects of the magnitude and time components of the voltage and current waveforms of the charge signal at the battery pack 204 may be measured and/or estimated. In general, several aspects of the voltage and current waveforms of the charge signal may be determined or measured to determine or estimate the impedance at the battery pack 204. In another implementation, hundreds or thousands of measurements of the voltage or current waveforms may be obtained and analyzed via a digital processing system. In general, higher fidelity and/or more measurements of the waveforms may provide a more accurate analysis of the impedance of the waveform as applied to battery pack 204 to better determine the harmonic components of the charge signal at which minimum impedance values occur or other aspects of the effect of the waveforms on the battery pack to determine the shape of energy signals of the charge signal.

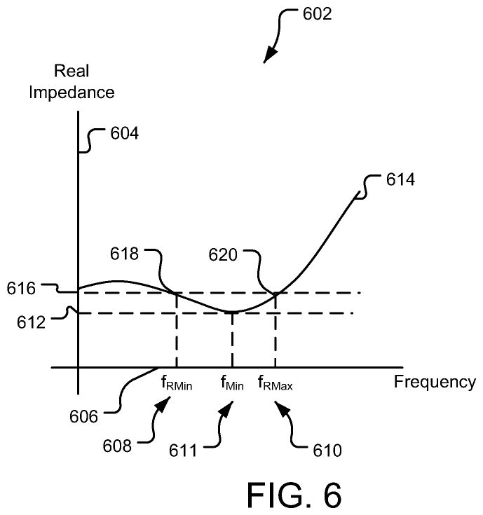

As mentioned above, the circuit controller 210 may generate harmonically tuned energy signals of a charge signal for a battery pack 204 based on a frequency corresponding to a minimum impedance value. A frequency or harmonic corresponding to a minimum impedance value may include a frequency at a determined minimum impedance value (either real or imaginary or both) or may be near the determined minimum impedance value. For example, the frequency may be between a frequency corresponding to a determined minimum real impedance value and a determined minimum imaginary impedance value, as those minimum values may occur at different frequencies. In another example, a range of frequencies corresponding to one or more minimum impedance values of the battery pack may be determined and a charge signal to the battery pack may be generated including harmonics within the range of identified frequencies. FIG. 6 illustrates a graph 602 of a maximum frequency 610 and a minimum frequency 608 ranging between acceptable, minimal impedance values, albeit not strictly at the minimum impedance frequency value. The graph 602 of FIG. 6 is similar to graph 402 of FIG. 4 discussed above in that it represents a plot of impedance values of a battery pack versus a frequency of a charge signal provided to the pack. In this example, rather than determining a frequency f_{Min} 412 corresponding to a minimum impedance value 410, a range of frequencies defined by a minimum frequency f_{RMin} 608 and a maximum frequency f_{RMax} 610 may be determined near the minimum impedance value 612 of the battery based on a range of acceptable impedance values for charging the battery cell. The range of acceptable impedance values may be based on a threshold impedance value. The minimum frequency f_{RMin} 608 and maximum frequency f_{RMax} 610, or any frequency within the range between the values, may be selected and included in a generated battery charge signal. Through the inclusion of multiple harmonics in the charge signal based on the range of frequencies at the acceptable impedance values, more charge than available from a single harmonic signal may be provided to recharge a battery pack while maintaining a smaller impedance at the battery cell receiving the charge energy signal.

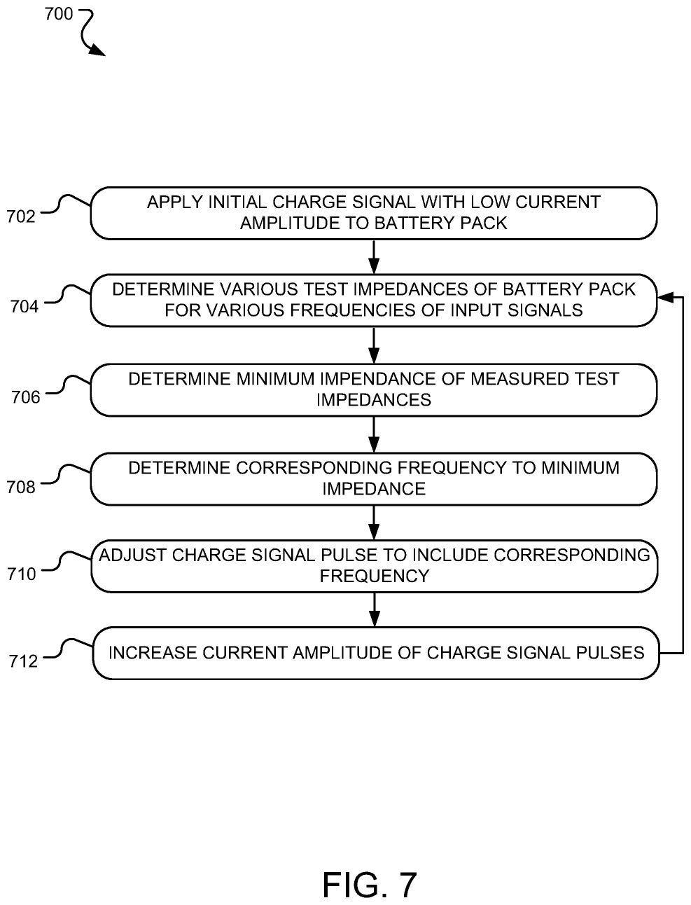

In one particular implementation illustrated in FIG. 7, a method 700 is provided for generating a charge signal for a battery pack based on a frequency corresponding to a minimum impedance value. The operations of the method 700 may be performed by a circuit controller 210 and, in particular, by providing control signals to the charge signal shaping circuit 206 to cause the shaping circuit to generate a shaped charge signal. Other circuit designs and components may also be controlled by the circuit controller 210 to perform one or more of the operations of the method 700.

Beginning in operation 702, the circuit controller 210 may select characteristics of an initial charge signal to apply to the battery pack 204 to begin balanced charging of the pack. For example, the circuit controller 210 may select an initial frequency for a charge signal to be used to recharge the battery pack 204. In one instance, a charge energy signal may be selected to recharge a pack 204 to avoid the inefficiencies of a conventional square-wave charge pulse. In other instances, the initial charge signal may include one or more energy signals similar to that illustrated in FIG. 5. The selected frequency may be determined to minimize or reduce the impedance at the battery pack 204 during the initial charging of the battery. In one particular implementation, the circuit controller 210 may obtain the initial frequency for the charge signal based on historical data of the battery pack 204, historical data of one or more cells 206 of the battery pack, historical data of similarly constructed battery packs, or other battery recharge data. The initial selected frequency may thus not correspond to a currently assessed minimum impedance value for a state of charge for the battery pack 204, but may rather be based on one or more historical impedance determinations for the target battery cell or any other battery cells. The initial charge signal may also have a low current amplitude. Applying a low current amplitude to the battery pack 204 initially may limit any harmful effects to the pack cells 206 that result from harmonics within the signal associated with high impedance values. In other words, because the harmonic associated with a low impedance of the battery cells 206 may not be known or is initially estimated, a relatively low current amplitude charge signal may be supplied to limit any possible negative or suboptimal effects on the battery pack 204 until the low impedance harmonic is determined, as explained in more detail below.

As mentioned above, the minimum impedance at the battery pack 204 may vary during the charging of the battery. For example, the state of charge and the temperature of the cells 206 of the battery pack 204 may alter minimum impedance characteristics of the pack as a whole. Adjusting the frequency of the energy signal charge signal to a frequency corresponding to a minimum impedance of the battery pack 204 at the current state of the battery may provide efficiency benefits to charging the battery pack. Therefore, the circuit controller 210 may, in operation 704, measure the impedance of the battery pack 204 or one or more cells 206 of the pack at various frequencies to obtain a function of impedance values of the battery pack at the various frequencies. In one implementation, the circuit controller 210 may apply one or more test signals at various frequencies to the battery pack 204 to determine a charge signal frequency corresponding to a measured minimum impedance at the battery pack. For each test or charge signal applied to the battery pack 204, a corresponding impedance value (either real or imaginary impedance) at the battery pack 204 may be determined and/or stored.

In operation 706, a minimum impedance value of the measured test impedances may be determined. In one instance, an imaginary impedance or reactance may be determined. Regardless, the circuit controller 210 may select a smallest impedance value from the received test results as the minimum impedance value. In another example, circuit controller 210 may analyze the received impedance values and extrapolate the values to determine a minimum real impedance value. For example, the measurement values may indicate that the impedance values are decreasing for a series of increasing test frequencies, followed by the measurement values increasing for a next series of increasing test frequencies. The circuit controller 210 may determine that a minimum impedance value for the battery pack 204 corresponds to a frequency between the first set of increase test frequencies and the second set of increasing test frequencies. In this circumstance, the circuit controller 210 may estimate a minimum impedance value for the battery pack 204 between the measured values.

In operation 708, the circuit controller 210 may determine a corresponding frequency to the determined minimum impedance value for the battery pack 204. For example, a graph 414 of impedance values 404 of the battery pack 204 or cells 206 of the pack to frequencies 406 of the test signals may be generated and a minimum impedance value 410 may be determined from the graph. A corresponding frequency to the minimum impedance value 410 may also be determined from the graph 414. In general, any correlating algorithm for determining a frequency of an input signal to a battery pack 204 resulting in a minimum impedance value may be utilized to determine the corresponding frequency.

In operation 710, the circuit controller 210 may determine if the frequency corresponding to the minimum impedance value of the measured test impedances is different than the previously selected frequency at which the charge signal is provided and adjust the charge signal to include the determined frequency. If the circuit controller 210 determines that the corresponding frequency obtained from application of the test signals to the battery pack 204 is different than the frequency at which the charge signal is being provided, the circuit controller 210 may include the frequency into the charge energy signal, such as in a leading edge of the charge energy signal. Further, in operation 712, the circuit controller 210 may further alter the charge signal to increase the current amplitude of the energy signals of the signal to increase the energy being supplied to the cells 206 of the battery pack 204. More particularly, because the charge signal includes harmonics aimed to reduce the impedance at the battery cells 206, the negative effects of high frequencies within the signal may be reduced such that a higher magnitude of current may be included in the charge signal to charge the cells faster while maintaining a charge balance between the cells of the battery pack 204. Following the generation of the shaped-energy signal charge signal, the method 700 may return to operation 704 to continue monitoring the frequency response of the battery pack 204 and/or cells 206 to the charge signal and adjusting of the charge signal according to the monitored characteristics of the battery pack.

In one example, the circuit controller 210 may calculate or otherwise obtain a combination of the real impedance values and the imaginary impedance values to select a frequency or harmonic at which an energy signal of a charge signal are generated. One such combination may include a modulus calculation of the real and imaginary impedance values. Other combinations of both components of the impedance at the battery may also be calculated or determined by the circuit controller 210 and used in shaping energy signals of a charge signal. For example, one or both of the real impedance and the imaginary impedance values may be weighted disproportionally (such as applying a 20% weight to the real impedance value and an 80% weight to the imaginary impedance value) or proportionally and may be used to determine different aspects of the energy signals of the charge signal, such as the leading edge or width of the charge energy signal. By considering both components of the impedance (real impedance and imaginary impedance) at the battery pack or cell, a more efficient charge signal may be generated. Consideration of both components of the impedance at the battery pack or cells of the pack may become particularly useful for systems with multiple cells in which impedance is added by the connections between the multiple cells.

In some instances, the circuit controller 210 may select a frequency for the charge signal that is different than either a frequency corresponding to a minimum real impedance value or a frequency corresponding to a minimum imaginary impedance value. Rather, the circuit controller 210 may balance the real impedance values and the imaginary impedance values to determine a harmonic for the charge signal such that the selected frequency for the charge signal may be any frequency associated with any identified harmonic profile associated with the battery pack.

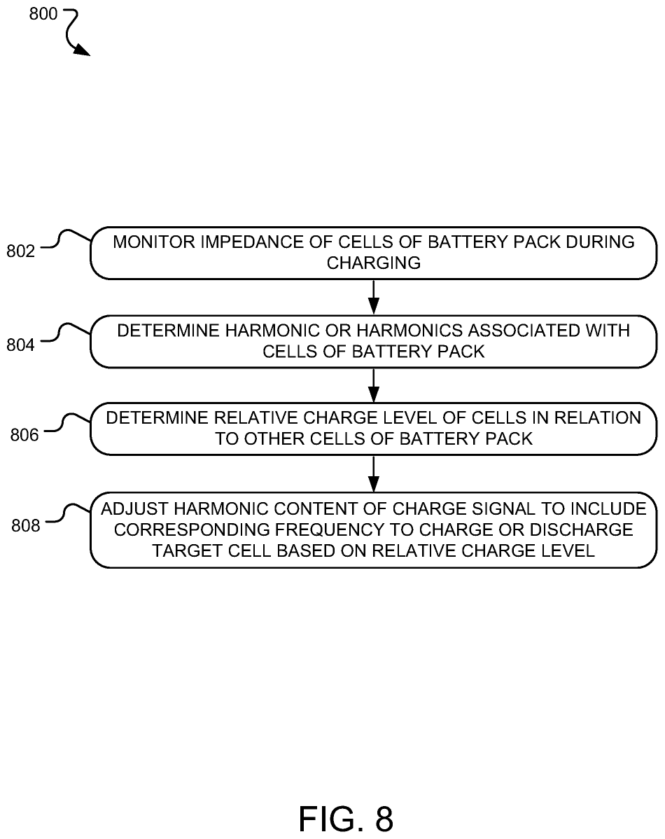

As mentioned above, characteristics of a charge signal, such as a harmonic of a leading edge of an energy signal of the signal, may be shaped to target a particular cell or cells within a battery pack 204. FIG. 8 is a flowchart of a method for generating a charge signal for a battery pack 204 to charge or discharge a cell 206 of the battery pack in accordance with one embodiment. Similar to above, the operations of the method 800 may be performed by a circuit controller 210 and, in particular, by providing control signals to the charge signal shaping circuit 206 to cause the shaping circuit to generate a shaped charge signal.

Beginning in operation 802, the circuit controller 210 may monitor the impedance of a cell or cells 206 of a battery pack 204 during charging of the pack. More particularly, the battery pack 204 may include one or more taps that provide an electrical connection to the interconnections of the cells 206 of the battery 204, such as that illustrated in the battery pack 304 of FIG. 3A. The taps provide electrical connections to the interior connection of the cells 206 such that various measurements may be obtained from the battery pack 204, such as measuring voltage, current, power, etc. associated with a cell or a group of cells of the battery pack, in contrast to the pack as a whole. The measurements may be utilized by the circuit controller 210 to determine characteristics of the cells of the battery pack 204, such as a real or imaginary impedance characteristic of the battery cells 206. Utilizing the battery pack 304 of FIG. 3A as an example, taps 312 and 314 may allow the circuit controller 210 and/or the impedance measurement circuit 208 to measure or determine an impedance of cell 306b. In particular, the circuit controller 210 may obtain a voltage difference between tap 312 and tap 314 and measure the current into cell 306b. An impedance of cell 306b may be a function of this determined voltage and current by dividing the voltage difference by the current through the cell at a given frequency. Similarly, taps 314 and 316 may allow the circuit controller 210 to measure or determine an impedance characteristic of cell 306c or a grouping of cells 306a through 306c. Cell 206 characteristics may also be obtained by the circuit controller 210 for one or more other cells of the battery pack 304 in a similar manner.

Through the monitored impedance of one or more of the cells 206 of the battery pack 204, the circuit controller 210 may associate particular harmonics of the charge signal with the different cells of the pack. For example, and as explained in greater detail above, an impedance graph may be generated for a first cell 206 of the battery pack 204 that can be used to identify a frequency or harmonic at which a low impedance value is present on that particular cell. As each cell 206 in the battery pack 204 may have different characteristics (such as cell composition, state of charge, temperature, etc.), each cell may have a different frequency associated with a low impedance at the cell. As such, a harmonic may be associated with one or more of the cells 206 of the battery pack 204 that corresponds to a low impedance value for that cell. In some instances, more than one cell 206 of the battery pack 204 may be associated with the same harmonic when the characteristics of the cells may be similar.

In operation 806, the circuit controller 210 may determine a relative charge for one or more of the cells 206 of the battery pack 204 to determine an imbalance of the charges of the cells. As discussed above, the cells 206 of the battery pack 204 may not charge at the same rate due to various characteristics or conditions of the cells of the pack, leading to an unbalanced charge of the battery pack. Over time, imbalances tend to grow; one advantage of the present technique, is that imbalances may be detected and quickly rectified while maintaining the charge rate of the overall process. The example of FIG. 1A illustrates one example of an unbalanced battery pack, with voltage differences being used as a reference for unbalance. The circuit controller 210 may thus determine a relative charge for each of the cells 206 of the battery pack 204 to determine if one or more cells has more or less charge when compared to the other cells of the pack. The circuit controller 210 may, therefore, determine which cells 206 within the battery pack 204 may have more or less charge than the other cells of the pack.

Balancing the charge of the cells 206 of the battery pack 204 may provide for a more efficient pack charge, as explained above. Thus, the circuit controller 210 may, based on the obtained charges of the cells, determine one or more cells that has a lesser or greater charge relative to other cells in the pack. For example, and returning to FIG. 1A, the circuit controller 210 may determine that cell 1 106a has the smallest charge of the cells 206 of the battery pack 204 and may attempt to increase the charge relative to other cells thereby balancing. In this particular example, balancing the charges of the cells 206 may include providing greater charge energy to cell 1 106a to align the charge of the cell with the other cells in the pack 204. As such, the circuit controller 210 may identify cell 1 as the target cell to which an adjustment in the charge may be applied. In another example, a cell 106e of the pack 204 may be identified as having a higher charge when compared to other cells in the pack. In such an example, the cell with the highest charge may be the target cell and adjustment to the charge of target cell may include discharging of the target cell.

In operation 808, the circuit controller 210 may adjust one or more characteristics of a charge signal energy signal to include a harmonic corresponding to the target cell (or cells). For example, the target cell may have a lesser charge than other cells in the pack and the charge signal may be altered to include the harmonic associated with the target cell. Because the target cell 206 has a low impedance at the harmonic, the cell may absorb a large portion of the charge signal energy signal such that the energy signal may be targeted to the target cell. Using the battery pack of FIG. 3A as an example, assume cell 306a (as shown in FIG. 1A as cell 106a) is undercharged with cells closer to cell 306e are more charged. Balancing of the charge of the cells 306 may occur by applying a lower impedance harmonic that is absorbed more heavily by the first cells (such cells 306a-306b) of the pack 304. Further, the lower impedance harmonics may be at least partially filtered out by the time the charge signal reaches cell 306e such that cell 306e absorbs less charge signal, effectively balancing the charge of the pack of cells. In some instances, the trailing edge could also have harmonics that may cause the charge energy signal to last longer for the first cells of the pack 304. In another example, cell 306e may be undercharged in comparison to the other cells such that the harmonics of the energy signal may be adjusted to be neutral (lowest possible reactance), immediately followed by a higher impedance discharge energy signal. This charge signal may partially discharge cells closest to cell 306a and attenuated as received at cell 306e, allowing cell 306e to catch up in charged capacity. A similar approach may be applied to cells in the middle of the chain.

For unbalanced cells in a parallel configuration, a charge signal may be applied through the cells 206 of a battery pack 204, particularly at frequencies near the steeper areas of the impedance vs frequency plot 402 of FIG. 4. Such a signal may cause the voltages of each cell 206 to shift at different rates, if the impedance of the cells at that frequency isn't matched to the others. Because chemical processes aren't perfectly reversible, the impedance of a cell to the positive portion of the charge signal would not be the same as the negative portion, and the cell may have some small net change in capacity as a result. In this case, an adjustment to the harmonics in the charge signal may be applied until the voltage of all cells start to fall in line, or until any increases in cell variation during charge are slowed or ceased.

In another example, the target cell may have more charge than other cells within the battery pack 204. In this situation, a trailing portion of the charge signal energy signal (such as section 516 of the waveform 522 of FIG. 5) may be altered to include a harmonic associated with the target cell. The trailing portion 516 may discharge the target cell such that the charge signal energy signal may be utilized to discharge cells that have a higher charge than other cells of the pack 204. Other charging or discharging portions of the charge signal may also be altered to target a particular cell or group of cells of the battery pack 204 to balance the charges of the cells of the pack. By adjusting or generating a charge signal energy signal with a particular harmonic, a charge of a cell 206 or cells of a battery pack 204 may be targeted to charge or discharge the cell. The charging or discharging of the cell may aid in balancing the charges of the cells of the battery pack 204. For example, by adjusting the charge signal energy signal to include a harmonic associated with the target cell 206, the cell may absorb energy from the charge signal to increase the charge of the cell, perhaps in response to the cell charge being less than other cells of the pack. In another example, adjusting a discharge portion of the charge signal energy signal to include a harmonic associated with the target cell may cause the cell to discharge energy and decrease the charge of the cell in instances in which the cell has a higher charge than other cells of the pack 204. In this manner, a harmonic associated with a cell 206 or cells of a battery pack 204 may be utilized to charge or discharge a target cell to aid in charge balancing of the cells within the pack.

Various embodiments discussed herein charge a battery pack by generating energy signals of a charge signal that correspond to a harmonic associated with an optimal transfer of energy based on a real and/or an imaginary value of the energy transfer of the battery pack, a plurality of cells of the battery pack, or a particular cell of the battery pack. Shaping the energy signals of the charge signal to correspond to the harmonic may aid in balanced charging of the cells of the battery pack. The charge signal may be shaped separately or in conjunction with a charge balancer in communication with the battery pack. In still other examples, energy signals of the charge signal may be shaped with a harmonic corresponding to a particular cell or group of cells of the battery pack to charge or discharge the particular cell. The target cell may be charged or discharged to further provide for a balanced cell charging of the battery pack.

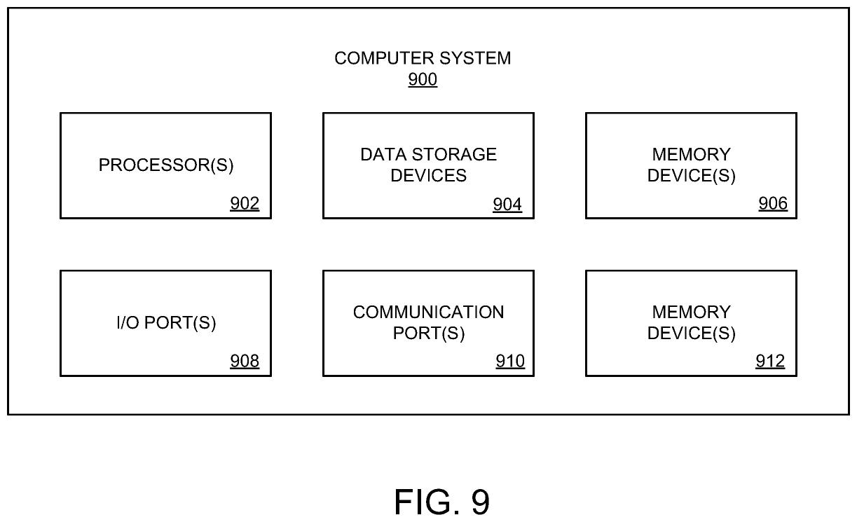

Referring to FIG. 9, a detailed description of an example computing system 900 having one or more computing units that may implement various systems and methods discussed herein is provided. The computing system 900 may be part of a controller, may be in operable communication with various implementation discussed herein, may run various operations related to the method discussed herein, may run offline to process various data for characterizing a battery, and may be part of overall systems discussed herein. The computing system 900 may process various signals discussed herein and/or may provide various signals discussed herein. For example, battery measurement information may be provided to such a computing system 900. The computing system 900 may also be applicable to, for example, the controller, the model, the tuning/shaping circuits discussed with respect to the various figures and may be used to implement the various methods described herein. It will be appreciated that specific implementations of these devices may be of differing possible specific computing architectures, not all of which are specifically discussed herein but will be understood by those of ordinary skill in the art. It will further be appreciated that the computer system may be considered and/or include an ASIC, FPGA, microcontroller, or other computing arrangement. In such various possible implementations, more or fewer components discussed below may be included, interconnections and other changes made, as will be understood by those of ordinary skill in the art.

The computer system 900 may be a computing system that is capable of executing a computer program product to execute a computer process. Data and program files may be input to the computer system 900, which reads the files and executes the programs therein. Some of the elements of the computer system 900 are shown in FIG. 9, including one or more hardware processors 902, one or more data storage devices 904, one or more memory devices 906, and/or one or more ports 908-912. Additionally, other elements that will be recognized by those skilled in the art may be included in the computing system 900 but are not explicitly depicted in FIG. 9 or discussed further herein. Various elements of the computer system 900 may communicate with one another by way of one or more communication buses, point-to-point communication paths, or other communication means not explicitly depicted in FIG. 9. Similarly, in various implementations, various elements disclosed in the system may or not be included in any given implementation.

The processor 902 may include, for example, a central processing unit (CPU), a microprocessor, a microcontroller, a digital signal processor (DSP), and/or one or more internal levels of cache. There may be one or more processors 902, such that the processor 902 comprises a single central-processing unit, or a plurality of processing units capable of executing instructions and performing operations in parallel with each other, commonly referred to as a parallel processing environment.

The presently described technology in various possible combinations may be implemented, at least in part, in software stored on the data stored device(s) 904, stored on the memory device(s) 906, and/or communicated via one or more of the ports 908-912, thereby transforming the computer system 900 in FIG. 9 to a special purpose machine for implementing the operations described herein.

The one or more data storage devices 904 may include any non-volatile data storage device capable of storing data generated or employed within the computing system 900, such as computer executable instructions for performing a computer process, which may include instructions of both application programs and an operating system (OS) that manages the various components of the computing system 900. The data storage devices 904 may include, without limitation, magnetic disk drives, optical disk drives, solid state drives (SSDs), flash drives, and the like. The data storage devices 904 may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), magneto-optical disks, flash drives, and the like. Examples of non-removable data storage media include internal magnetic hard disks, SSDs, and the like. The one or more memory devices 906 may include volatile memory (e.g., dynamic random-access memory (DRAM), static random access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 904 and/or the memory devices 906, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 900 includes one or more ports, such as an input/output (I/O) port 908, a communication port 910, and a sub-systems port 912, for communicating with other computing, network, or vehicle devices. It will be appreciated that the ports 908-912 may be combined or separate and that more or fewer ports may be included in the computer system 900. The I/O port 908 may be connected to an I/O device, or other device, by which information is input to or output from the computing system 900. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 900 via the I/O port 908. In some examples, such inputs may be distinct from the various system and method discussed with regard to the preceding figures. Similarly, the output devices may convert electrical signals received from computing system 900 via the I/O port 908 into signals that may be sensed or used by the various methods and system discussed herein. The input device may be an alphanumeric input device, including alphanumeric and other keys for communicating information and/or command selections to the processor 902 via the I/O port 908.

The environment transducer devices convert one form of energy or signal into another for input into or output from the computing system 900 via the I/O port 908. For example, an electrical signal generated within the computing system 900 may be converted to another type of signal, and/or vice-versa. In one implementation, the environment transducer devices sense characteristics or aspects of an environment local to or remote from the computing device 900, such as battery voltage, open circuit battery voltage, charge current, battery temperature, light, sound, temperature, pressure, magnetic field, electric field, chemical properties, and/or the like.

In one implementation, a communication port 910 may be connected to a network by way of which the computer system 900 may receive network data useful in executing the methods and systems set out herein as well as transmitting information and network configuration changes determined thereby. For example, charging protocols may be updated, battery measurement or calculation data shared with external system, and the like. The communication port 910 connects the computer system 900 to one or more communication interface devices configured to transmit and/or receive information between the computing system 900 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 910 to communicate with one or more other machines, either directly over a point-to-point communication path, over a wide area network (WAN) (e.g., the Internet), over a local area network (LAN), over a cellular (e.g., third generation (3G), fourth generation (4G), fifth generation (5G)) network, or over another communication means.

The computer system 900 may include a sub-systems port 912 for communicating with one or more systems related to a device being charged according to the methods and system described herein to control an operation of the same and/or exchange information between the computer system 900 and one or more sub-systems of the device. Examples of such sub-systems of a vehicle, include, without limitation, motor controllers and systems, battery management systems, and others.

The system set forth in FIG. 9 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

Embodiments of the present disclosure include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software and/or firmware.

Various modifications and additions can be made to the exemplary embodiments discussed without departing from the scope of the present invention. For example, while the embodiments, also referred to as implementations or examples, described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and, such references mean at least one of the embodiments.

Reference to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only, and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims, or can be learned by the practice of the principles set forth herein.

We claim:

1. A method for charging an electrochemical device comprising:
accessing a plurality of harmonic profiles that each indicate a relationship between at least one harmonic and an impedance of each of a plurality of electrochemical cells arranged in an electrochemical pack;
determining a relative charge value for each of the plurality of electrochemical cells; and
controlling, based on the relative charge value for each of the plurality of electrochemical cells, an energy signal at an electrode of the electrochemical pack, the energy signal at a harmonic associated with a target impedance value of a target electrochemical cell of the plurality of electrochemical cells.

2. The method of claim 1, wherein at least a portion of the plurality of electrochemical cells are connected in a series connection.

3. The method of claim 1, wherein at least a portion of the plurality of electrochemical cells are connected in a parallel connection.

4. The method of claim 1, wherein the energy signal comprises one of a charge current, a discharge current, a charge voltage, a discharge voltage, a charge power, or a discharge power.

5. The method of claim 1, wherein the target electrochemical cell is directly connected to the electrode of the electrochemical pack.

6. The method of claim 1, wherein at least one other electrochemical cell of the plurality of electrochemical cells is connected between the target electrochemical cell and the electrode of the electrochemical pack.

7. The method of claim 1, wherein a portion of the energy signal is absorbed by the target electrochemical cell based on the harmonic associated with the target impedance value to increase the relative charge value of the target electrochemical cell.

8. The method of claim 1, wherein a portion of the energy signal is absorbed by the target electrochemical cell based on the harmonic associated with the target impedance value to decrease the relative charge value of the target electrochemical cell.

9. The method of claim 1, wherein controlling the energy signal balances the relative charge values of the plurality of electrochemical cells of the electrochemical device.

10. A battery pack charging system comprising:
a charge signal shaping circuit in communication with an electrochemical pack comprising a plurality of electrochemical cells;
an impedance measurement circuit in communication with the electrochemical pack to obtain an impedance measurement of each of plurality of electrochemical cells; and
a controller to:
determine a relative charge value for each of the plurality of electrochemical cells;
identify, based on the relative charge value for each of the plurality of electrochemical cells, a target electrochemical cell of the plurality of electrochemical cells; and
control the charge signal shaping circuit to shape a charge signal for the target electrochemical cell based on a harmonic associated with a target impedance value of the target electrochemical cell.

11. The battery pack charging system of claim 10, wherein the harmonic is associated with a target real impedance value of the electrochemical device.

12. The battery pack charging system of claim 10, wherein the harmonic is associated with a target imaginary impedance value of the electrochemical device.

13. The battery pack charging system of claim 10, wherein the harmonic is associated with a combination of a real impedance value and an imaginary impedance value of the electrochemical device.

14. The battery pack charging system of claim 10, wherein the harmonic is associated with a reactance of the electrochemical device.

15. The battery pack charging system of claim 10, wherein a portion of the charge signal is absorbed by the target electrochemical cell based on the harmonic associated with the target impedance value to increase the relative charge value of the target electrochemical cell.

16. The battery pack charging system of claim 10, wherein a portion of the energy signal is absorbed by the target electrochemical cell based on the harmonic associated with the target impedance value to decrease the relative charge value of the target electrochemical cell.

17. The battery pack charging system of claim 10 further comprising:
a power source providing a power signal and wherein controlling the charge signal shaping circuit comprises siphoning energy from the power signal to provide the charge signal.

18. A method for balance charging of a battery pack, the method comprising:
obtaining, based on an indication of a charge of a first cell of a plurality of electrochemical cells being less than an indication of a charge of a second cell of the plurality of electrochemical cells, a target impedance value of the first cell; and
shaping a charge signal for the plurality of electrochemical cells to include a harmonic associated with the target impedance value of the first cell, the charge signal to charge the first cell.

19. The method of claim 18 further comprising:
obtaining, based on an indication of a charge of a third cell of the plurality of electrochemical cells being more than an indication of a charge of a fourth cell of the plurality of electrochemical cells, a target impedance value of the third cell; and
shaping a charge signal for the plurality of electrochemical cells to include a harmonic associated with the target impedance value of the third cell, the charge signal to discharge the third cell.

20. The method of claim 18 wherein the first cell and the second cell of the plurality of electrochemical cells are connected in a series connection.

21. The method of claim 18 wherein the first cell and the second cell of the plurality of electrochemical cells are connected in a parallel connection.

22. The method of claim 18 wherein shaping the charge signal comprises:
controlling a charge signal shaping circuit to shape the charge signal to include the harmonic associated with the target impedance value of the first cell.

23. The method of claim 18 wherein the harmonic is associated with a reactance of the first cell of the plurality of electrochemical cells.

24. The method of claim 18 wherein the indication of the charge of the first cell of the plurality of electrochemical cells corresponds to a measured voltage potential across the first cell.
